(19) United States
(12) Patent Application Publication
(10) Pub. No.: US 2025/0293541 A1
(43) Pub. Date: Sep. 18, 2025

(54) DATA CENTER BACKUP POWER SYSTEM

(71) Applicant: Takanock, Inc., Traverse City, MI (US)

(72) Inventors: Kenneth Davies, Traverse City, MI (US); Timothy Campbell, Traverse City, MI (US)

(73) Assignee: Takanock, Inc., Traverse City, MI (US)

(21) Appl. No.: 19/081,472

(22) Filed: Mar. 17, 2025

Related U.S. Application Data
(60) Provisional application No. 63/566,036, filed on Mar. 15, 2024.

(51) Int. Cl. H02J 9/06

(52) U.S. Cl. CPC H02J 9/066

(57) ABSTRACT

According to one example, a system includes a backup power system for providing backup power to all or a portion of a data center. The backup power system includes a turbine plant that has one or more turbines, and further includes one or more uninterruptible power sources. Following a power outage to all or a portion of the data center, the one or more uninterruptible power sources may provide the backup power to all or a portion of the data center, and the one or more turbines of the turbine plant may start a start up process. Following the one or more turbines finishing the start up process, the turbine plant may provide the backup power to all or a portion of the data center.

### CROSS REFERENCE TO RELATED APPLICATIONS

This application claims the benefit of priority to U.S. Provisional Patent Application No. 63/566,036 filed Mar. 15, 2024, the entirety of which is incorporated herein by reference.

### TECHNICAL FIELD

This disclosure relates generally to data centers, and more specifically to a data center backup power system.

### BACKGROUND

A data center is a facility or location that can be used to store data and/or applications. In general, a data center includes one or more computing systems, hardware equipment, and/or networking equipment, such as, for example, servers, data storage systems, routers, switches, firewalls, any other computing system(s), hardware equipment, and/or networking equipment, or any combination of the preceding. A data center tends to use a large amount of power (i.e., electricity) to, for example, keep the computing systems, hardware equipment, and/or networking equipment operational, to provide security measures for the data center, and to provide cooling systems for the systems and equipment. Furthermore, a data center may be at risk to power outages, which can put the data center at a high risk of operational loss (e.g., loss of stored data, etc.). Traditional data centers may utilize backup power systems to provide backup power to the data center, and therefore reduce the risk to the data center. These traditional backup power systems, however, may be deficient.

### SUMMARY

According to one example, a system includes a backup power system for providing backup power to all or a portion of a data center. The backup power system includes a turbine plant that has one or more turbines, and further includes one or more uninterruptible power sources. Following a power outage to all or a portion of the data center, the one or more uninterruptible power sources may provide the backup power to all or a portion of the data center, and the one or more turbines of the turbine plant may start a start up process. Following the one or more turbines finishing the start up process, the turbine plant may provide the backup power to all or a portion of the data center.

According to another example, a system includes a backup power system for providing backup power to all or a portion of a data center. The backup power system includes one or more generators, and one or more generator switchboards. Following a power outage to all or the portion of the data center, the one or more generator switchboards may receive power generated by the one or more generators, and provide the power over a first pathway to one or more main switchboards to be provided as backup power to all or a portion of the data center. Prior to the power outage or following a fix of the power outage to all or a portion of the data center, the one or more generator switchboards may receive the power generated by the one or more generators, and provide the power over a second pathway to be provided as dispatch power to a utility power grid, where the second pathway skips the one or more main switchboards.

### BRIEF DESCRIPTION OF THE FIGURES

For a more complete understanding of the present disclosure and one or more examples of the features and advantages of the present disclosure, reference is now made to the following description, taken in conjunction with the accompanying drawings, in which:

FIG. 1 illustrates an example data center power system that includes an example backup power system having a turbine plant.

FIG. 2 illustrates another example data center power system that includes an example backup power system having a turbine plant and generator(s).

FIGS. 3-5 illustrate examples of fuel storage for a backup power system, such as the backup power systems of FIGS. 1-2.

FIG. 6 illustrates an example data center power system that includes an example backup power system having generator(s), generator switchboard(s), and dispatch transformer(s).

FIG. 7 illustrates another example data center power system that includes an example backup power system having generator(s), generator switchboard(s), and dispatch transformer(s).

FIG. 8 illustrates a further example of a data center power system that includes a backup power system having a turbine plant, generator(s), generator switchboard(s), and dispatch transformer(s).

### DETAILED DESCRIPTION

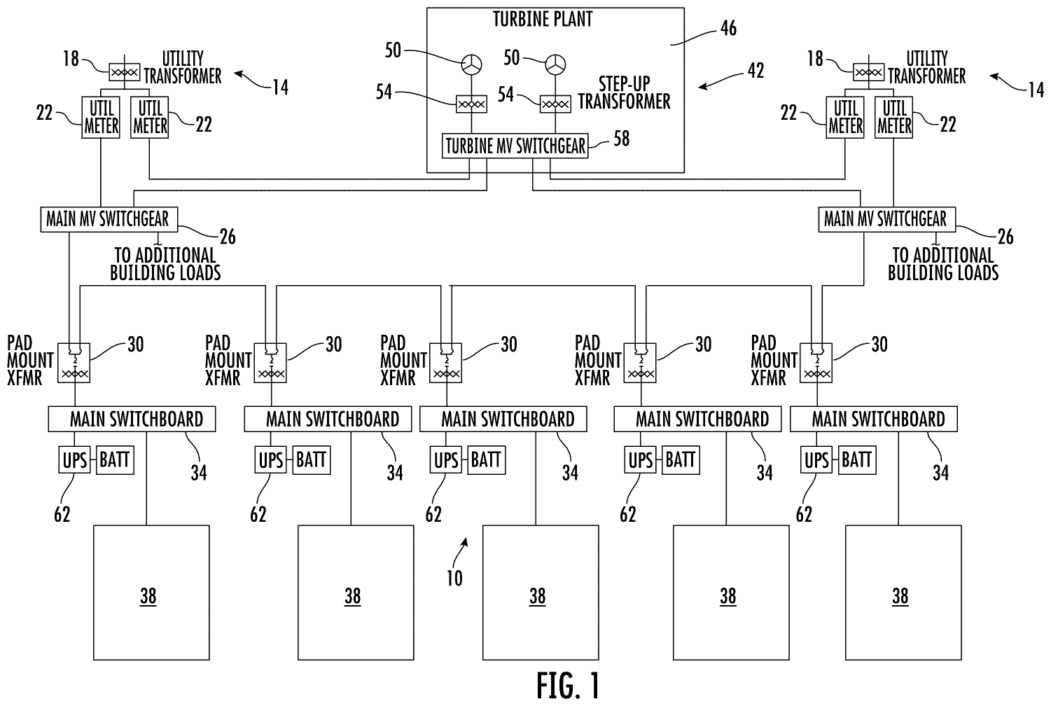

Examples in the present disclosure are best understood by referring to FIGS. 1-8 of the drawings, like numerals being used for like and corresponding parts of the various drawings.

A data center is a facility or location that can be used to store data and/or applications. In general, a data center includes one or more computing systems, hardware equipment, and/or networking equipment, such as, for example, servers, data storage systems, routers, switches, firewalls, any other computing system(s), hardware equipment, and/or networking equipment, or any combination of the preceding. A data center tends to use a large amount of power (i.e., electricity) to, for example, keep the computing systems, hardware equipment, and/or networking equipment operational, to provide security measures for the data center, and to provide cooling systems for the systems and equipment. Furthermore, a data center may be at risk to power outages, which can put the data center at a high risk of operational loss (e.g., loss of stored data, etc.).

Traditional data centers may utilize backup power systems to provide backup power to a data center, and therefore reduce the risk to the data center. These traditional backup power systems, however, may be deficient. In particular, traditional backup power systems tend to utilize diesel-powered generators to provide backup power to a data center. However, as data centers grow in size and power needs, the number of diesel-powered generators needed increases. For example, a data center may need 10 or more (or even 100s of) diesel-powered generators distributed throughout the data center (e.g., with one or more generators being located at different buildings or portions of the data center). This number of diesel-powered generators (and the fact that they are distributed throughout the data center) requires a significant amount of space at the data center or adjacent to the data center. Not only may this space not be available, but it may severely restrict the ability of the data center to expand later (as the room for expansion may already be taken up by the diesel-powered generators).

In contrast to this, in some examples, the backup power system of FIGS. 1-5 and 8 may address one or more of these deficiencies. For example, the backup power system of FIGS. 1-5 and 8 may include a turbine plant that may be used to provide backup power to the data center. The turbine plant may take up less space than the cumulation of diesel-powered generators used in traditional systems, in some examples. Furthermore, in some examples, the turbine plant may be consolidated into a single plant location (e.g., that may be offsite of the data center, or that may be located in a separate location from the data center). This may, in some examples, prevent diesel-powered generators from having to be distributed throughout the data center.

FIG. 1 illustrates an example data center power system 10 that includes a backup power system 42. In the example illustrated in FIG. 1, the backup power system 42 includes a turbine plant 46 that may be used to provide backup power to the data center 38, and that further includes a uninterruptible power supply (UPS) 62 that may also be used to provide backup power to the data center 38. In general, when a data center 38 experiences a power outage (e.g., due to utility grid failures, rolling blackouts, inclement weather, natural or man-made disasters, and/or electrical failure), the UPS 62 may provide backup power to the data center 38 while the turbine plant 46 starts up (e.g., turns on, warms up, and fully accepts the power load). Once the turbine plant 46 has finished starting up, the turbine plant 46 may provide backup power to the data center 38 until the power outage is fixed.

In the example illustrated in FIG. 1, the data center power system 10 includes one or more utility connections 14 that allow electricity to be provided to the data center 38 from a utility supplier (e.g., a power company). The utility connection 14 may include any component(s) that may allow electricity to be provided to the data center 38 from a utility supplier. Examples of these components include one or more utility transformers 18 and one or more utility meters 22.

The utility transformer 18 may be any device or equipment that transforms higher transmission level voltage (e.g., above 35 kV) to distribution voltage (e.g., 12 kV-35 kV). In some examples, the utility transformer 18 may be referred to as a distribution transformer or a service transformer. The utility transformer 18 receives electricity provided by the utility supplier (e.g., a power company), and the utility transformer 18 transforms the voltage of the electricity (i.e., steps down the voltage) from the higher transmission level voltage to the distribution voltage, in some examples. The utility transformer 18 may be located in a utility substation. This substation may be on the premises of the data center 38 (e.g., on-premise), or off the premises (e.g., off-premise).

The utility meter 22 may be any device or equipment that measures the power consumption of the data center 38. The utility meter 22 is the point of common coupling between the data center 38 and the utility supplier (e.g., a power company).

The data center power system 10 may include any number of utility connections 14, and each utility connection 14 may include any number of components that may allow electricity to be provided to the data center 38 from a utility supplier, such as any number of utility transformers 18 and/or utility meters 22. In the illustrated example in FIG. 1, the data center power system 10 includes two utility connections 14. One utility connection 14 may be the primary connection, while the other utility connection 14 may be a redundant connection that may be utilized when the primary connection is not working and/or for concurrent maintainability, in some examples.

In the example illustrated in FIG. 1, the data center power system 10 further includes one or more main switchgears 26. The main switchgear 26 may be any device or equipment that may receive electricity from the utility supplier, and that may further distribute the electricity as needed (e.g., distribute it to different portions of the data center 38). In some examples, the main switchgear 26 may be a switchgear manufactured by Schneider Electric, Eaton, ABB, or Siemens. In some examples, the main switchgear 26 may be a medium voltage switchgear that uses voltages between 1 kV and 52 kV. The main switchgear 26 is the first point of medium voltage termination of the utility supplier to the equipment of the data center 38, in some examples. The main switchgear 26 may include bussing, breakers, protective relays, and/or metering. The breakers are used for distribution of electricity to one or more portions of the data center 38 (e.g., to different buildings in the data center 38, to different floors of a data center 38, etc.). Furthermore, the main switchgear 26 may include electrical disconnect switches, fuses, and/or circuit breakers used to control, protect, and isolate electrical equipment. As such, the main switchgear 26 may be used to both de-energize equipment to allow work to be done, and to clear faults downstream, in some examples.

The data center power system 10 may include any number of main switchgears 26. In the example illustrated in FIG. 1, the data center power system 10 includes two main switchgears 26. One main switchgear 26 may be the primary main switchgear, while the other main switchgear 26 may be a redundant main switchgear that may be utilized when the primary main switchgear 26 is not working, in some examples.

In the example illustrated in FIG. 1, the data center power system 10 further includes one or more pad mounted transformers 30. The pad mounted transformer 30 may be any device or equipment that may receive electricity from the main switchgear 26, and that may further transform the voltage of the electricity (i.e., steps down the voltage) from a medium voltage distribution voltage (e.g., 1 kV-52 kV) to a building voltage (e.g., 600 V or less).

The data center power system 10 may include any number of pad mounted transformers 30. In the example illustrated in FIG. 1, the data center power system 10 includes five pad mounted transformers 30, where each pad mounted transformer 30 is used to provide electricity to a single main switchboard 34. However, any other number of pad mounted transformers 30 may be used, and any other ratio of pad mounted transformers 30 to main switchboards 34 may be used.

In the example illustrated in FIG. 1, the data center power system 10 further includes one or more main switchboards 34. The main switchboard 34 may be any device or equipment that may receive electricity (e.g., from the pad mounted transformer 30, from the UPS 62, from a generator), and may supply the electricity to a portion of the data center 38. That is, the main switchboard 34 may serve as a building service entrance for the portion of the data center 38, in some examples. The main switchboard 34 may include various components, such as, for example, controls, metering, and distribution breakers. In some examples, the main switchboard 34 may include (or otherwise work in conjunction with) a transfer switch (e.g., an automatic transfer switch) or controls that operate as a transfer switch. These controls or transfer switch may transfer between two sources of electricity (e.g., from the pad mounted transformer 30 to the UPS 62, or vice versa), in some examples. In further examples, these controls or transfer switch may also initiate operation of the UPS 62 and/or generator(s), if any. In some examples, the main switchboard 34 may be a switchboard manufactured by Schneider Electric, Eaton, ABB, Anord, or Siemens.

The data center power system 10 may include any number of main switchboards 34. In the example illustrated in FIG. 1, the data center power system 10 includes five main switchboards 34, where each main switchboard 34 is used to provide electricity to a single portion of the data center 38. However, any other number of main switchboards 34 may be used, and any other ratio of main switchboards 34 to portions of the data center 38 may be used.

As is discussed above, the main switchboard 34 supplies electricity to the data center 38 (or a portion of the data center 38). The data center 38 may be a facility or location that can be used to store data and/or applications. In general, the data center 38 includes one or more computing systems, hardware equipment, and/or networking equipment, such as, for example, servers (e.g., rack servers, blade servers), data storage systems (e.g., block storage devices, file storage devices), routers, switches, firewalls, any other computing system(s), hardware equipment, and/or networking equipment, or any combination of the preceding. Examples of a data center include, for example, a GOOGLE data center, an AWS data center, a MICROSOFT data center, any other data center, or any combination of the preceding.

As is also discussed above, a data center 38 may include one or more portions. A portion of a data center 38 may be a building of the data center 38 (where each building is its own portion of the data center 38), a floor of the data center 38 (where each building is its own portion of the data center 38), an electrical circuit of the data center 38 (where each electrical circuit is its own portion of the data center 38), a section of the data center 38 (e.g., security section, data storage section, networking section), any other portion, any multiples of the preceding (e.g., two buildings or two floors may be a single portion of the data center 38), or any combination of the preceding. The data center 38 may include any number of portions. For example, the data center 38 may include only a single portion. As another example, the data center 38 may include 10 or more portions, or even hundreds of portions. In the example illustrated in FIG. 1, the data center power system 10 includes five portions of the data center 38.

In the example illustrated in FIG. 1, the data center power system 10 further includes a backup power system 42 that may provide backup power to the data center 38 when the data center 38 experiences a power outage (e.g., due to utility grid failures, rolling blackouts, inclement weather, natural or man-made disasters, and/or electrical failure).

In the example illustrated in FIG. 1, the backup power system 42 includes a turbine plant 46 that may be used to provide backup power to the data center 38. The turbine plant 46 may be any type of turbine plant 46. In the example illustrated in FIG. 1, the turbine plant 46 is a multi-fuel turbine plant that can utilize different types of fuels to generate electricity. As one example of this, the turbine plant 46 may utilize natural gas (from storage and/or from a pipeline), hydrogen (e.g., from a pipeline) or liquid fuel (e.g., diesel, propane, natural gas liquids, etc.) to generate electricity. In some examples, the turbine plant 46 may be consolidated into a single plant location (as opposed to traditional diesel-powered generators that may be distributed throughout the data center 38). The turbine plant 46 may be located in a single plant location (or multiple plant locations) offsite of the data center 38, or it may be located in a single plant location (or multiple plant locations) on the premises of the data center 38 (i.e., on-premise). In the illustrated example, the turbine plant 46 is consolidated into a single plant location (e.g., a stand alone power plant) located on the premises of the data center 38.

In the example illustrated in FIG. 1, the turbine plant 46 includes one or more turbines 50. The turbine 50 may be any turbine-based device or equipment that can convert a fuel and/or other energy into mechanical energy via a turbine, where the mechanical energy can be supplied to a generator (or other device) to generate electricity. In the illustrated example, the turbine 50 is a gas turbine. The gas turbine may draw in air (e.g., at the front of the unit), compress the air, mix the air with fuel, and ignite the mixture, causing gases to expand through turbine blades—which creates mechanical energy. This mechanical energy may then be supplied to a generator (or other device) to generate electricity. Examples of the turbine 50 include the Solar Titan 350 SoLoNOx, GE LM 2500v Express, any other suitable gas turbine, or any combination of the preceding.

The turbine 50 (when connected to a generator) may generate any amount of power (i.e., electricity). For example, each turbine 50 may generate approximately 30 mW to 40 mW of nominal power output. As another example, each turbine 50 may generate approximately 30 mW to 38 mW of nominal power output. To generate the power, the turbine 50 may utilize any type of fuel and/or other energy. For example, the turbine 50 may be a multi-fuel gas turbine that can utilize different types of fuels to generate power (i.e., electricity). For example, the turbine 50 may utilize natural gas (from storage and/or from a pipeline) or liquid fuel (e.g., diesel, propane, natural gas liquids, etc.) to generate electricity.

The turbine plant 46 may include any number of turbines 50, and the turbines 50 may be arranged in any configuration. The number of turbines 50 in the turbine plant 46 may be based on the power needs of the data center 38. Furthermore, in some examples, the turbine plant 46 may include twice as many (or more than twice as many) turbines 50 to provide for the power needs of the entire data center 38 (or one or more portions of the data center 38, such as only the critical portions of the data center 38). In such an example, a first set of turbine(s) 50 may be primary turbine(s) for providing backup power, and a second set of turbine(s) 50 may be redundant turbine(s) for providing backup power if the first set of turbine(s) 50 are malfunctioning or otherwise not providing sufficient power. In the illustrated example, the turbine plant 46 includes two turbines 50.

As is discussed above, the turbine 50 may include or otherwise be connected to a generator (or other device) that generates electricity. Additionally, the turbine 50 may include or otherwise be connected to any other components that may be used or needed to assist in the operation of the turbine 50 and/or to generate electricity.

In the example illustrated in FIG. 1, the turbine plant 46 further includes one or more turbine plant transformers 54. The turbine plant transformer 54 may be any device or equipment that may receive electricity from the turbine 50 (and generator, if any), and that may further transform the voltage of the electricity (i.e., steps up the voltage) from a building voltage (e.g., 600 V or less) to a medium voltage distribution voltage (e.g., 1 kV-52 kV).

The turbine plant 46 may include any number of turbine plant transformers 54. In the illustrated example, the turbine plant 46 includes two turbine plant transformers 54, where each turbine plant transformer 54 receives electricity from a turbine 50 (and generator, if any). However, any other number of turbine plant transformers 54 may be used, and any other ratio of turbine plant transformers 54 to turbines 50 may be used.

In the example illustrated in FIG. 1, the turbine plant 46 further includes one or more turbine main switchgears 58. The turbine main switchgear 58 may be any device or equipment that may receive electricity generated at the turbine plant 46, and that may further distribute the electricity as needed (e.g., distribute it to the main switchgear 26, which may then further distribute the electricity as needed, as is discussed above). In some examples, the turbine main switchgear 58 may be a switchgear manufactured by Schneider Electric, Eaton, ABB, or Siemens. In some examples, the turbine main switchgear 58 may be a medium voltage switchgear that uses voltages between 1 kV and 52 kV. The turbine main switchgear 58 may include bussing, breakers, protective relays, and/or metering. The breakers are used for distribution of electricity to the main switchgear 26 (or any other equipment or device). Furthermore, the turbine main switchgear 58 may include electrical disconnect switches, fuses, and/or circuit breakers used to control, protect, and isolate electrical equipment. As such, the turbine main switchgear 58 may be used to both de-energize equipment to allow work to be done, and to clear faults downstream, in some examples.

The turbine plant 46 may include any number of turbine main switchgears 58. In the illustrated example, the turbine plant 46 includes one turbine main switchgear 58.

In the example illustrated in FIG. 1, the backup power system 42 further includes one or more UPSs 62 that may also be used to provide backup power to the data center 38. The UPS 62 may be any device or equipment that can provide continuous power to the data center 38 (or one or more critical loads of the data center 38) when there is a power outage. For example, the UPS may be a battery-powered UPS, a flywheel-powered UPS, any other type of device or equipment that can reliably supply uninterrupted power to the data center 38, or any combination of the preceding. In the illustrated example, the UPS 62 is a battery-powered UPS. In operation, the UPS 62 may provide near-instantaneous protection from input power interruptions by switching to stored energy. In the illustrated example, the UPS 62 includes a battery (e.g., lithium or lead) that can store enough energy to provide sufficient electricity to a portion of the data center 38 for 20 minutes or more (or approximately 20 minutes or more). This 20 minute timeframe may provide enough time for the turbine plant 46 to start up and begin providing power to the data center 38. In other examples, the UPS 62 may store enough energy (or have access to enough stored energy) to provide sufficient electricity to a portion of the data center 38 for any other time frame, such as 1 hour, 45 minutes, 30 minutes, 15 minutes, or any other timeframe.

The backup power system 42 may include any number of UPSs 62. In the illustrated example, the backup power system 42 includes five UPSs 62, where each UPS 62 is used to provide electricity to a single main switchboard 34. However, any other number of UPSs 62 may be used, and any other ratio of UPSs 62 to main switchboards 34 may be used.

In some examples, the data center power system 10 and/or backup power system 42 includes a control system (not illustrated) that allows for the automatic and/or manual operation of one or more of the components of the data center power system 10 and/or backup power system 42. For example, the control system may be used to automatically and/or manually control the turbine plant 46 (and it components), automatically and/or manually control the main switchboard(s) 34, automatically and/or manually control the main switchgear(s) 26, automatically and/or manually control any of the other components of the data center power system 10 and/or backup power system 42, or any combination of the preceding.

As one example of the operation of the data center power system 10, power (i.e., electricity) may primarily be provided to the data center 38 from a utility supplier (via utility connection(s) 14, main switchgear(s) 26, pad mounted transformer(s) 30, and main switchboard(s) 34). However, if there is a power outage (e.g., due to utility grid failures, rolling blackouts, inclement weather, natural or man-made disasters, and/or electrical failure), power (i.e., electricity) may then be temporarily provided to the data center 38 from the backup power system 42. As one example of this, the power outage may automatically (or manually) cause the UPS(s) 62 to provide electricity to the data center 38 (via the main switchboard(s) 34). Similarly, the power outage may also automatically (or manually) cause the turbine plant 46 to begin its start up process (e.g., turn on, warm up, and fully accept the power load). In some examples, this start up process may take approximately 30 minutes. During this time, the UPS(s) 62 may provide electricity to the data center 38 (via the main switchboard(s) 34). Once the turbine plant 46 has finished the start up process (i.e., it can now fully accept the power load), the turbine plant 46 may provide electricity to the data center 38 (via main switchgear(s) 26, pad mounted transformer(s) 30, and main switchboard(s) 34). The turbine plant 46 may continue to provide electricity until the power outage is fixed, at which point the electricity may once again be provided to the data center 38 from the utility supplier.

As is discussed above, the data center power system 10 may utilize the turbine plant 46 to provide electricity to the data center 38 as a backup power source. However, the turbine plant 46 is not limited to use as only a backup power source, in some examples. Instead, in some examples, the turbine plant 46 may also be used to provide electricity back into the utility grid (e.g., to the utility supplier). For example, as is illustrated in FIG. 1, the turbine plant 46 may be connected to the utility connection(s) 14 via the turbine main switchgear 58. This may allow the turbine plant 46 to generate electricity and provide that electricity to the utility grid in order to monetize the turbine plant 46. In such an example, when fuel costs for the turbine plant 46 are less than payouts for providing electricity to the utility grid, the turbine plant 46 may be started up so as to provide electricity to the utility grid. While the turbine plant 46 is providing electricity to the utility grid, the utility grid may also be providing electricity to the data center 38 (as is explained above). As such, the turbine plant 46 can be used to monetize its generated electricity when there is no power outage (e.g., when the turbine plant 46 is not being used for backup power for the data center 38 (or any other critical facility)). In some examples, the turbine plant 46 may provide electricity to the utility grid through a utility interconnect meter (which is in addition to the standard utility service meter). This may keep the separation from the data center standard operation.

Modifications, additions, or omissions may be made to data center power system 10 and/or backup power system 42 without departing from the scope of the disclosure. For example, one or more components of data center power system 10 and/or backup power system 42 may be separated, combined, and/or eliminated. As one example of this, one or more of the transformers discussed above may be eliminated as needed.

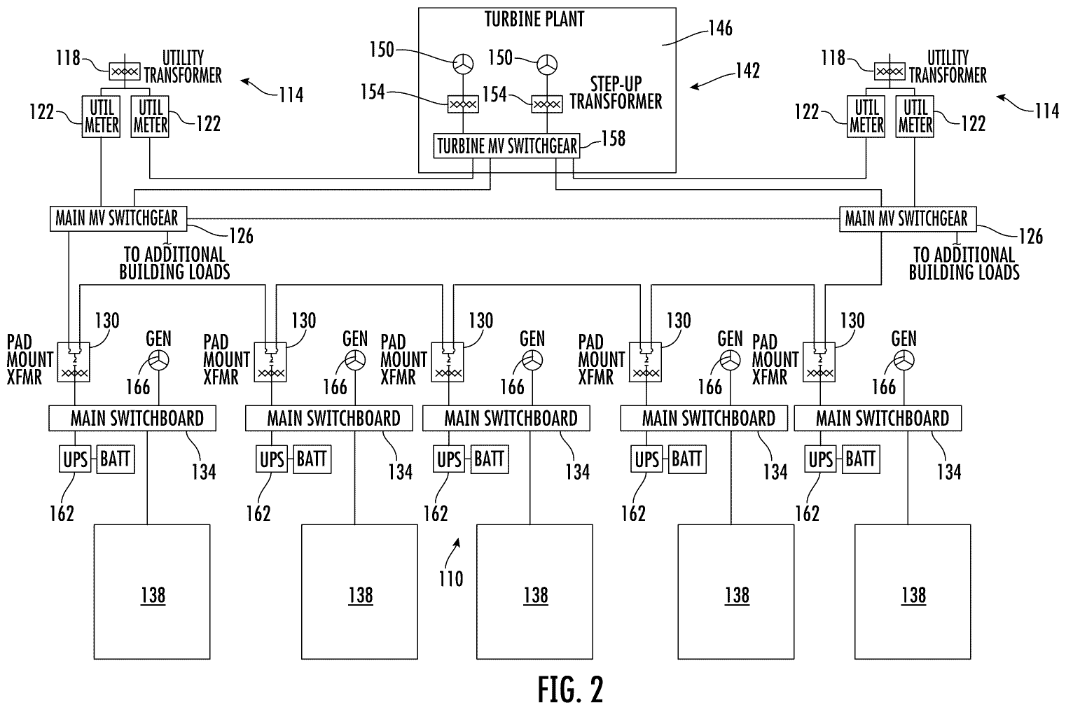

FIG. 2 illustrates an example data center power system 110 that includes another example backup power system 142. In the example illustrated in FIG. 2, the backup power system 142 includes (1) a turbine plant 146 that may be used to provide backup power to the data center 138, (2) one or more generators 166 that may also be used to provide backup power to the data center 138, and (3) one or more UPSs 162 that may also be used to provide backup power to the data center 138. In general, when a data center 138 experiences a power outage (e.g., due to utility grid failures, rolling blackouts, inclement weather, natural or man-made disasters, and/or electrical failure), the UPS(s) 162 may provide backup power (i.e., electricity) to the data center 138 while the turbine plant 146 starts up (e.g., turns on, warms up, and fully accepts the power load), and further while the generator(s) 166 start up (e.g., turn on, warm up, and fully accept the power load). Once the generator(s) 166 have finished the start up (i.e., they can fully accept the power load), the generator(s) 166 may provide backup power to the data center 138 until the turbine plant 146 finishes its starts up. Once the turbine plant 146 has finished its start up (i.e., it can fully accept the power load), the turbine plant 146 may provide backup power to the data center 138 until the power outage is fixed.

In the example illustrated in FIG. 2, the data power system 110 and the backup power system 142 include one or more utility connections 114, one or more utility transformers 118, one or more utility meters 122, one or more main switchgears 126, one or more pad mounted transformers 130, one or more main switchboards 134, a data center 138 (e.g., one or more portions of the data center 138), a turbine plant 146, one or more turbines 150, one or more turbine plant transformers 154, one or more turbine main switchgears 158, and one or more UPSs 162. The utility connection(s) 114, utility transformer(s) 118, utility meter(s) 122, main switchgear(s) 126, pad mounted transformer(s) 130, main switchboard(s) 134, turbine plant 146, turbine(s) 150, turbine plant transformer(s) 154, turbine main switchgear(s) 158, and UPS(s) 162 are the same as (or substantially similar) to the utility connection(s) 14, utility transformer(s) 18, utility meter(s) 22, main switchgear(s) 26, pad mounted transformer(s) 30, main switchboard(s) 34, turbine plant 46, turbine(s) 50, turbine plant transformer(s) 54, turbine main switchgear(s) 58, and UPS(s) 62 of FIG. 1 (discussed above). Furthermore, the data center 138 of FIG. 2 is the same as (or substantially similar to) the data center 38 of FIG. 1 (discussed above).

However, unlike FIG. 1, the backup power system 142 of FIG. 2 further includes one or more generators 166 that may also be used to provide backup power to the data center 138. The generator 166 may be any device or equipment that may generate electricity. In the example illustrated in FIG. 2, the generator 166 is a gas-powered generator that converts gas into electricity. The electricity generated by the generator 166 may be provided to the main switchboard 134, which may provide the electricity as backup power to the data center 138.

The backup power system 142 may include any number of generators 166, and any configuration of the generators 166 In the illustrated example, the backup power system 142 includes five generators 166 distributed throughout the data center 138, where each generator 166 is used to provide electricity to a single main switchboard 134. However, any other number of generators 166 may be used, any other ratio of generators 166 to main switchboards 134 may be used, and any other configuration of the generators 166 may be used.

Additionally, unlike FIG. 1, the UPS 62 includes a battery (e.g., lithium or lead) that can store enough energy to provide sufficient electricity to the data center 138 (or a portion of the data center 138) for 20 minutes or less (or approximately 20 minutes or less), such as 5 minutes (as opposed to 20 minutes or more discussed in FIG. 1). This 5 minute timeframe may provide enough time for the generators 166 to start up and begin providing power to the data center 138. In other examples, the UPS 162 may store enough energy (or have access to enough stored energy) to provide sufficient electricity to the data center 138 for any other time frame, such as 1 hour, 45 minutes, 20 minutes, 15 minutes, 1 minute, or any other timeframe.

In some examples, the data center power system 110 and/or backup power system 142 may include a control system (not illustrated) that allows for the automatic and/or manual operation of one or more of the components of the data center power system 110 and/or backup power system 142. For example, the control system may be used to automatically and/or manually control the turbine plant 146 (and it components), automatically and/or manually control the generator(s) 166, automatically and/or manually control the main switchboard(s) 134, automatically and/or manually control the main switchgear(s) 126, automatically and/or manually control any of the other components of the data center power system 110 and/or backup power system 142, or any combination of the preceding.

As one example of the operation of the data center power system 110, power (i.e., electricity) may primarily be provided to the data center 138 from a utility supplier (via utility connection(s) 114, main switchgear(s) 126, pad mounted transformer(s) 130, and main switchboard(s) 134). However, if there is a power outage (e.g., due to utility grid failures, rolling blackouts, inclement weather, natural or man-made disasters, and/or electrical failure), electricity may then be temporarily provided to the data center 138 from the backup power system 142. As one example of this, the power outage may automatically (or manually) cause the UPS(s) 162 to provide electricity to the data center 138 (via the main switchboard(s) 134). Similarly, the power outage may also automatically (or manually) cause the generator(s) 166 to start their start up process (e.g., turn on, warm up, and fully accept the power load), and may further also automatically (or manually) cause the turbine plant 146 to start its start up process (e.g., turn on, warm up, and fully accept the power load). In some examples, the start up process of the generators 166 may take approximately 5 minutes. During this time, the UPS(s) 162 may provide electricity to the data center 138 (via the main switchboard(s) 134). Once the generator(s) 166 have finished the start up process (i.e., they fully accept the power load), the generator(s) 166 may provide electricity to the data center 138 (via the main switchboard(s) 134). Additionally, in some examples, the start up process of the turbine plant 146 may take approximately 25 more minutes (e.g., for a total of 30 minutes). During this time, the generators 166 may provide electricity to the data center 138 (via the main switchboard(s) 134). Once the turbine plant 146 has finished the start up process (e.g., it can fully accept the power load), the turbine plant 146 may provide electricity to the data center 138 (via main switchgear(s) 126, pad mounted transformer(s) 130, and main switchboard(s) 134). The turbine plant 146 may continue to provide electricity until the power outage is fixed, at which point the electricity may once again be provided to the data center 138 from the utility supplier.

Additionally, the turbine plant 146 is not limited to use as only a backup power source, in some examples. Instead, in some examples, the turbine plant 146 may also be used to provide electricity back into the utility grid (e.g., to the utility supplier), as is discussed above with regard to FIG. 1. Furthermore, the generator(s) 166 is also not limited to use as only a backup power source, in some examples. Instead, in some examples, the generators(s) 166 may also be used to provide electricity back into the utility grid (e.g., to the utility supplier). In such examples, the electricity may be provided to the utility grid via the main switchboard(s) 134, the pad mounted transformer(s) 130, the main switchgears(s) 126, and the utility connection(s) 114.

Modifications, additions, or omissions may be made to data center power system 110 and/or backup power system 142 without departing from the scope of the disclosure. For example, one or more components of data center power system 110 and/or backup power system 142 may be separated, combined, and/or eliminated. As one example of this, one or more of the transformers discussed above may be eliminated as needed.

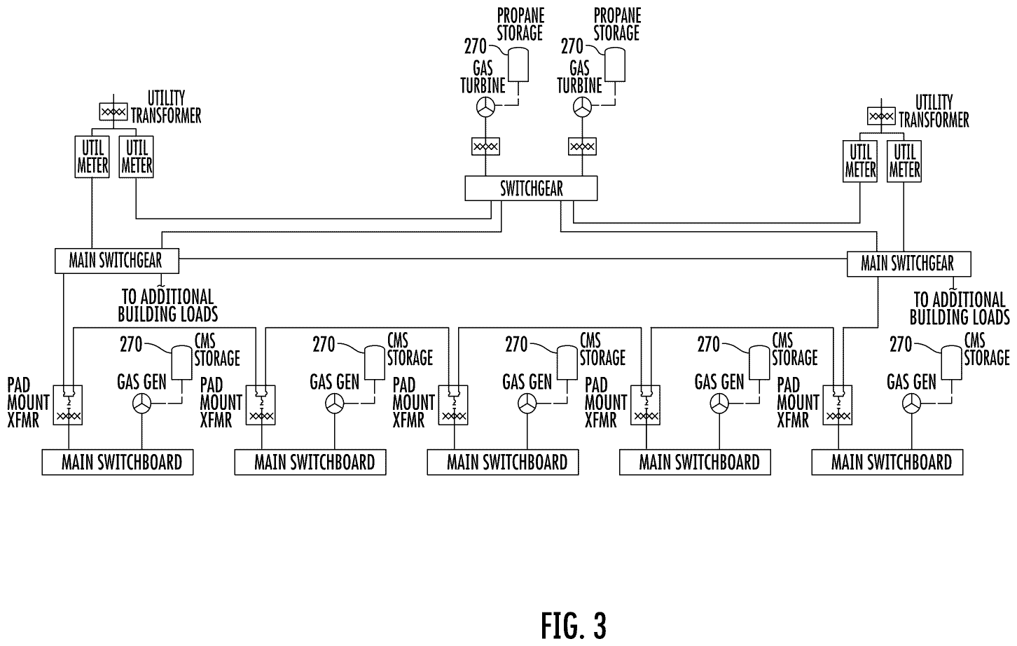

FIGS. 3-5 illustrate examples of fuel storage for a data center backup power system. Although the fuel storage in FIGS. 3-5 is illustrated as being used with the backup power system 142 of FIG. 2, the fuel storage in FIGS. 3-5 may be used with the backup power system 42 of FIG. 1, any other backup power system, or any combination of the preceding.

FIG. 3 illustrates an example where each turbine (e.g., turbine 50 of FIG. 1 or turbine 150 of FIG. 2) has its own dedicated on-site fuel storage tank 270, and also where each generator (e.g., generator 166 of FIG. 2) also has its own dedicated on-site fuel storage tank 270. The fuel storage tank 270 may have any size for storing any amount of fuel. For example, the fuel storage tank 270 for a turbine may store enough fuel for at least 24 hours (or even at least 48 hours) of continuous operation of the turbine. This may, in some examples, provide enough run-time for the turbine plant (e.g., turbine plant 46 of FIG. 1 or turbine plant 146 of FIG. 2) until firm pipeline gas supply is secured or until the fuel storage tanks 270 can be re-filled (which may allow for securing no-notice gas service and avoid elevated pipeline charges). As such, the turbine plant (e.g., turbine plant 46 of FIG. 1 or turbine plant 146 of FIG. 2) may be able to continue to run until the fuel storage tanks 270 are replenished. As another example, the fuel storage tank 270 for a generator may store enough fuel for at least 30 minutes of run-time. This may, in some examples, provide enough run-time for the generators (e.g., generators 166 of FIG. 2) until the turbine plant (e.g., turbine plant 46 of FIG. 1 or turbine plant 146 of FIG. 2) can start-up and accept the load.

The fuel storage tank 270 may also store any type of fuel. For example, the fuel storage tank 270 may store diesel gas, propane gas (e.g., propane natural gas liquids), natural gas liquids, ethanol, liquidified natural gas, compressed natural gas, or any other fuel. In the illustrated example, the fuel storage tanks 270 for the turbines (e.g., turbine 50 of FIG. 1 or turbine 150 of FIG. 2) store propane, and the fuel storage tanks 270 for the generators (e.g., generators 166 of FIG. 2) store compressed natural gas.

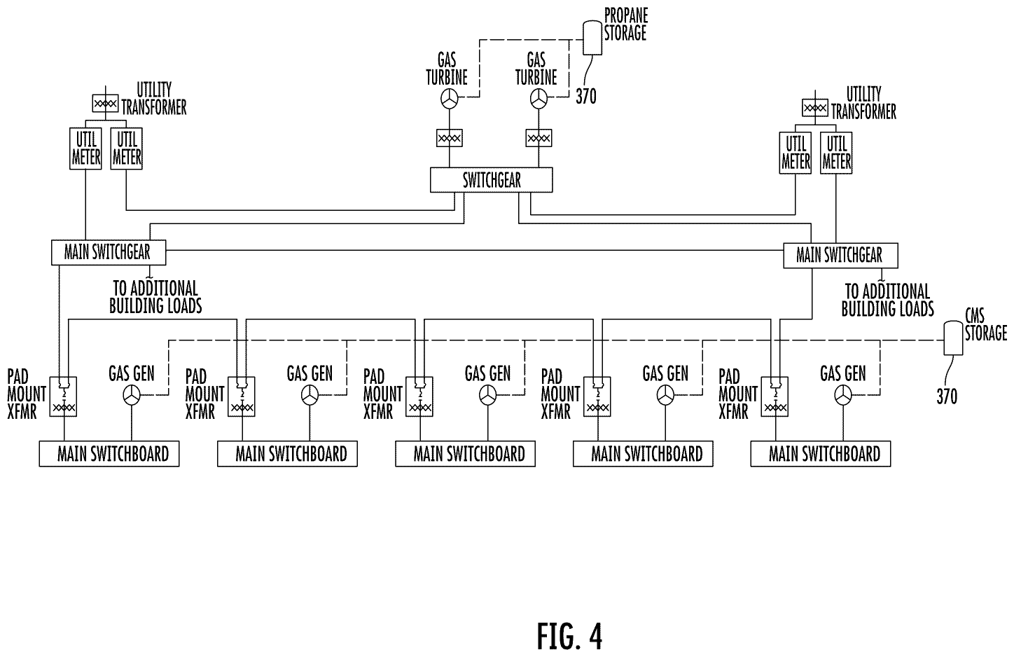

FIG. 4 illustrates an example where each turbine (e.g., turbine 50 of FIG. 1 or turbine 150 of FIG. 2) utilizes a shared on-site fuel storage tank 370, and also where each generator (e.g., generator 166 of FIG. 2) also utilizes a shared on-site fuel storage tank 370. Similar to that discussed above with regard to FIG. 3, each shared on-site fuel storage tank may have any size for storing any amount of fuel (e.g., at least 24 hours of continuous operation of the turbines, and at least 30 minutes of continuous operation of the generators), and may also store any type of fuel. In the illustrated example, the fuel storage tanks 370 for the turbines (e.g., turbine 50 of FIG. 1 or turbine 150 of FIG. 2) store propane, and the fuel storage tanks 370 for the generators (e.g., generators 166 of FIG. 2) store compressed natural gas.

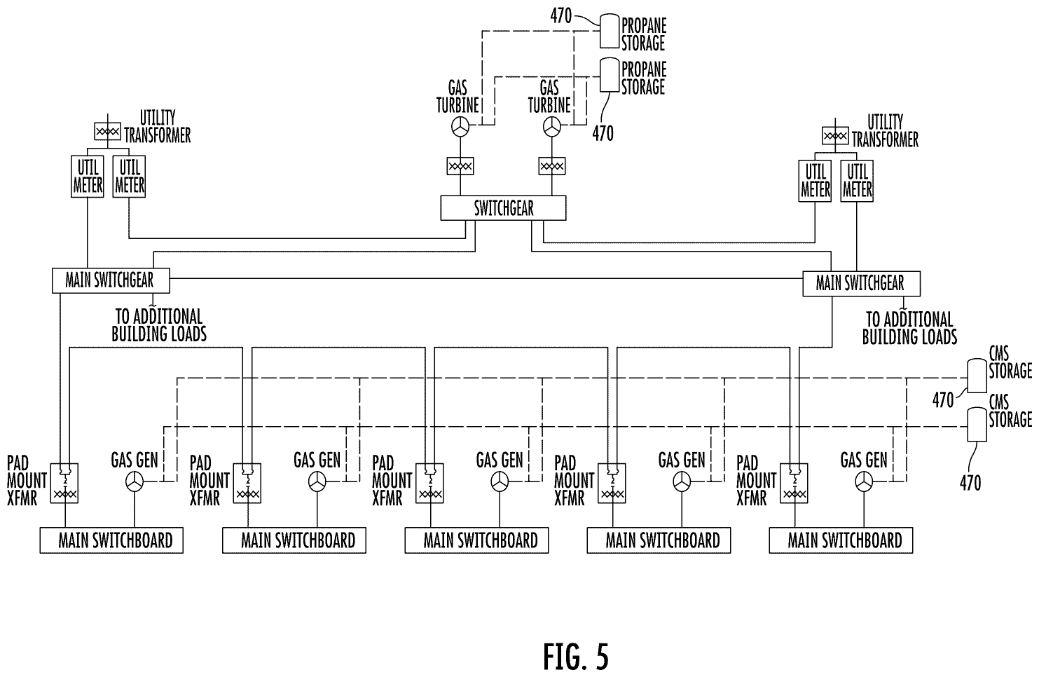

FIG. 5 illustrates an example where each turbine (e.g., turbine 50 of FIG. 1 or turbine 150 of FIG. 2) utilizes a shared on-site fuel storage tank 470 and a redundant on-site fuel storage tank 470, and also where each generator (e.g., generator 166 of FIG. 2) also utilizes a shared on-site fuel storage tank 470, and a redundant on-site fuel storage tank 470. The redundant fuel storage tank 470 may, in some examples, be used when the primary fuel storage tank 470 is not operating or is empty. Similar to that discussed above with regard to FIG. 4, each shared on-site fuel storage tank 470 may have any size for storing any amount of fuel (e.g., at least 24 hours of continuous operation of the turbines, and at least 30 minutes of continuous operation of the generators), and may also store any type of fuel. In the illustrated example, the fuel storage tanks 470 for the turbines (e.g., turbine 50 of FIG. 1 or turbine 150 of FIG. 2) store propane, and the fuel storage tanks 470 for the generators (e.g., generators 166 of FIG. 2) store compressed natural gas.

Although each of FIGS. 3-5 illustrate particular fuel storage types, the fuel storage types illustrated in each of FIGS. 3-5 may be combined with one or more of the other fuel storage types of the other figures. For example, FIG. 3 could be combined with FIG. 5 to include a primary dedicated on-site fuel storage tank 270 and a redundant dedicated on-site fuel storage tank 270 for each turbine and each generator. As another example, FIG. 3 could be combined with FIG. 4 so that all of the turbines utilize a shared on-site fuel storage tank 370, while all of the generators each utilize a dedicated on-site fuel storage tank 270 (or vice versa).

As is discussed above, traditional data centers may utilize backup power systems to provide backup power to the data center, and therefore reduce the risk to the data center. These traditional backup power systems, however, may be deficient. For example, the backup power systems for a data center are traditionally limited to only providing power to the data center, itself. This, however, prevents the backup power systems from being monetized by providing power to the utility power grid.

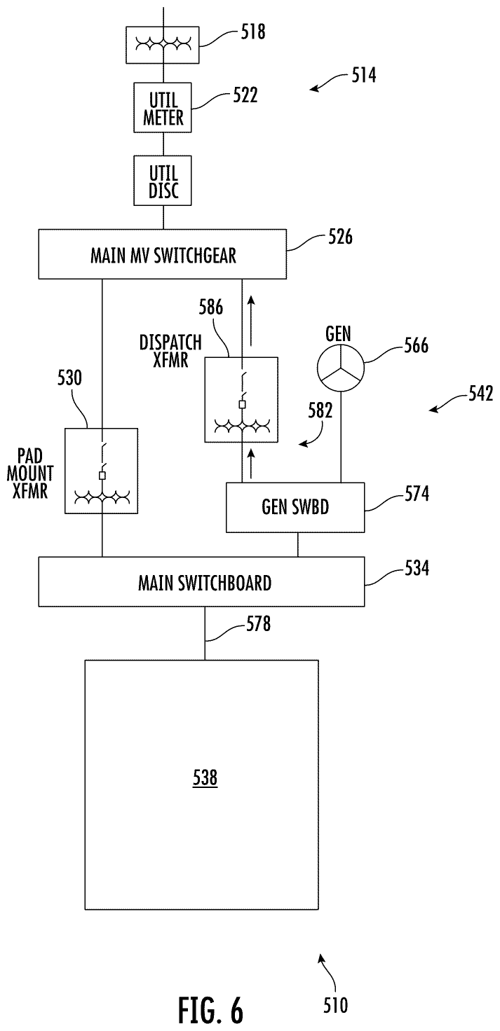

In contrast to this, in some examples, the backup power system of FIGS. 6-8 may address one or more of these deficiencies. For example, the backup power system of FIGS. 6-8 may include a generator switchboard that provides for two pathways for electricity generated by the backup power system. The first pathway may provide backup power (i.e., electricity) downstream to the main switchboard in order be provided to the data center. Alternatively, the second pathway may provide power (i.e., electricity) upstream to the main switchgear in order to be provided to the utility power grid. This may, in some examples, allow power to be provided to the utility power grid (e.g., for monetization). Additionally, in some examples, the power provided to the utility power grid may skip (e.g., not pass through) the main switchboard. For example, the generator switchboard and the second pathway may allow for an alternate path for on-site backup generation to supply building load or supply dispatch power to the utility power grid without causing action to primary transformation or downstream equipment including but not limited to the main switchboard (or switchgear, in some examples).

FIG. 6 illustrates an example data center power system 510 that includes a backup power system 542. In the example illustrated in FIG. 6, the backup power system 542 includes one or more generators 566 that may generate electricity that may be used for backup power for the data center 538 and/or that may be provided to the utility grid (e.g., for monetization). In general, when the generated electricity is provided to the utility grid, it may be provided to a generator switchboard 574 that sends the electricity to the utility grid via a second pathway 582 that skips (i.e., does not pass through) a main switchboard.

In the example illustrated in FIG. 6, the data center power system 510 includes one or more utility connections 514, one or more utility transformers 518, one or more utility meters 522, one or more main switchgears 526, one or more pad mounted transformers 530, and one or more main switchboards 534. The utility connection(s) 514, utility transformer(s) 518, utility meter(s) 522, main switchgear(s) 526, pad mounted transformer(s) 530, and main switchboard(s) 534 are the same as (or substantially similar) to the utility connection(s) 14/114, utility transformer(s) 18/118, utility meter(s) 22/122, main switchgear(s) 26/126, pad mounted transformer(s) 30/130, and main switchboard(s) 34/134 of FIGS. 1-5 (discussed above). Furthermore, the data center 538 of FIG. 6 is the same as (or substantially similar to) the data center 38/138 of FIGS. 1-5 (discussed above). As such, electricity may primarily be provided to the data center 538 from a utility supplier (via utility connection(s) 514, main switchgear(s) 526, pad mounted transformer(s) 530, and main switchboard(s) 534).

In the example illustrated in FIG. 6, the data center power system 510 further includes a backup power system 542 that includes one or more generators 566 that may generate electricity. The generator 566 is the same as (or substantially similar to) the generator 166 of FIGS. 2-5.

In the example illustrated in FIG. 6, the backup power system 542 further includes a generator switchboard 574, a first pathway 578, a second pathway 582, and a dispatch transformer 586.

The generator switchboard 574 may be any device or equipment that may receive electricity (e.g., from the generator 566), and that may supply the electricity to the main switchboard(s) 534 via the first pathway 578 (to be provided as backup power to the data center 538) and/or that may supply the electricity to the utility grid via the second pathway 582. The generator switchboard 574 may include various components, such as, for example, controls, metering, and distribution breakers. In some examples, the generator switchboard 574 may include (or otherwise work in conjunction with) a transfer switch (e.g., an automatic transfer switch) or controls that operate as a transfer switch. These controls or transfer switch may switch between the first pathway 578 and the second pathway 582 (thereby controlling where the electricity is provided to). The generator switchboard 574 is sized for the full rating of the generator 566, in the illustrated example. In some examples, the generator switchboard 574 may be a switchboard manufactured by Schneider Electric, Eaton, ABB, Anord, or Siemens.

The backup power system 542 may include any number of generator switchboards 574. In the illustrated example, the data center power system 510 includes one generator switchboard 574. In some examples, the backup power system 542 may include one generator switchboard 574 for each generator 566. However, any other ratio of generator switchboards 574 to generators 566 may be used.

The first pathway 578 includes any components and connections (including those included in the generator switchboard 574, if any) that allows electricity to be transferred from the generator switchboard 574 to the main switchboard(s) 534 (in order to be provided to the data center 538 or a portion of the data center 538 as backup power).

The second pathway 582 includes any components and connections (including those included in the generator switchboard 574, if any) that allows electricity to be transferred from the generator switchboard 574 to the main switchgear 526 (in order to be provided to the utility grid as dispatch power). As is illustrated in FIG. 6, the second pathway 582 includes the dispatch transformer 586. Furthermore, as is also illustrated in FIG. 6, the second pathway 582 skips the main switchboard(s) 534 (and also skips the pad mounted transformer(s) 530). As such, the backup power system 542 can be used to monetize its generated electricity without the operation of the main switchboard 534 transfer switch, in some examples.

The dispatch transformer 586 may be any device or equipment that may receive electricity from the generator switchboard 574, and that may further transform the voltage of the electricity (i.e., steps up the voltage) from a building voltage (e.g., 600 V or less) to a medium voltage distribution voltage (e.g., 1 kV-52 kV) or to a utility distribution voltage (12 kV-35 kV). This electricity may then be provided to the main switchgear 526 via the remainder of the second pathway 582 (in order to be provided to the utility grid as dispatch power).

The backup power system 542 may include any number of dispatch transformers 586. In the illustrated example, the backup power system 542 includes one dispatch transformer 586. In some examples, the backup power system 542 may include one dispatch transformer 586 for each generator 566 and/or for each generator switchboard 574. However, any other ratio of dispatch transformers 586 to generators 566 and/or generator switchboards 574 may be used.

In some examples, the data center power system 510 and/or backup power system 542 may include a control system (not illustrated) that allows for the automatic and/or manual operation of one or more of the components of the data center power system 510 and/or backup power system 542. For example, the control system may be used to automatically and/or manually turn on the generator(s) 566, automatically and/or manually control the generator switchboard(s) 574 (e.g., to determine which pathway to utilize), automatically and/or manually control the main switchboard(s) 534, automatically and/or manually control the main switchgear(s) 526, automatically and/or manually control any of the other components of the data center power system 510 and/or backup power system 542, or any combination of the preceding.

In some examples, the control system allows for the operation of the generator 566 to supply power through the dispatch transformer 586 upstream to the main switchgear 526 to support full building load, peak shaving operations, or additional capacity for dispatch into the utility power grid. The controls and automation within the data center power system 510 and/or backup power system 542 shall perform this function and transfer to standby or emergency operations when called upon per the control system, in some examples.

As one example of the operation of the data center power system 510, power (i.e., electricity) may primarily be provided to the data center 538 from a utility supplier (via utility connection(s) 514, main switchgear(s) 526, pad mounted transformer(s) 530, and main switchboard(s) 534).

However, if there is a power outage (e.g., due to utility grid failures, rolling blackouts, inclement weather, natural or man-made disasters, and/or electrical failure), power (i.e., electricity) may then be temporarily provided to the data center 538 from the backup power system 542. As one example of this, the power outage may automatically (or manually) cause the generator(s) 566 to start up, begin generating electricity, and accept the full power load. The generator(s) 566 may then provide electricity to the generator switchboard 574, which may provide the electricity, via the first pathway 578, to the main switchboard 534 (to be provided to the data center 538 as backup power). The backup power system 542 may continue to provide electricity until the power outage is fixed, at which point the electricity may once again be provided to the data center 538 from the utility supplier.

Additionally, the backup power system 542 may also be used to provide power (i.e., electricity) back into the utility grid (e.g., when there is no power outage). This may allow the backup power system 542 to generate electricity and provide that electricity to the utility grid in order to monetize the backup power system 542. In such an example, when fuel costs for the backup power system 542 are less than payouts for providing electricity to the utility grid, the backup power system 542 may be started up so as to provide electricity to the utility grid. The generator(s) 566 may then provide electricity to the generator switchboard 574, which may provide the electricity, via the second pathway 582 and the dispatch transformer 586, to the main switchgear 526 (in order to be provided to the utility grid as dispatch power). In some examples, the main switchgear 526 may provide electricity to the utility grid through a utility interconnect meter (which is in addition to the standard utility service meter).

In some examples, while the backup power system 542 is providing electricity to the utility grid, the utility grid may also be providing electricity to the data center 538. As such, the backup power system 542 can be used to monetize its generated electricity when there is no power outage (e.g., when the generator(s) 566 are not being used for backup power for the data center 538 (or any other critical facility)), in some examples. In the example illustrated in FIG. 6, the main switchgear 526 may receive electricity from the utility grid (to be provided to the data center 538) at the same time (e.g., simultaneously) it is also receiving electricity from the backup power system 542 (from the second pathway 582, so as to be provided to the utility grid as dispatch power).

Modifications, additions, or omissions may be made to data center power system 510 and/or backup power system 542 without departing from the scope of the disclosure. For example, one or more components of data center power system 510 and/or backup power system 542 may be separated, combined, and/or eliminated. As one example of this, one or more of the transformers discussed above may be eliminated as needed. Additionally, in some examples, the backup power system 542 may also include one or more UPSs (e.g., UPSs 62, or UPS 162) that may provide backup power to the data center 538 while the generator(s) 566 are starting up.

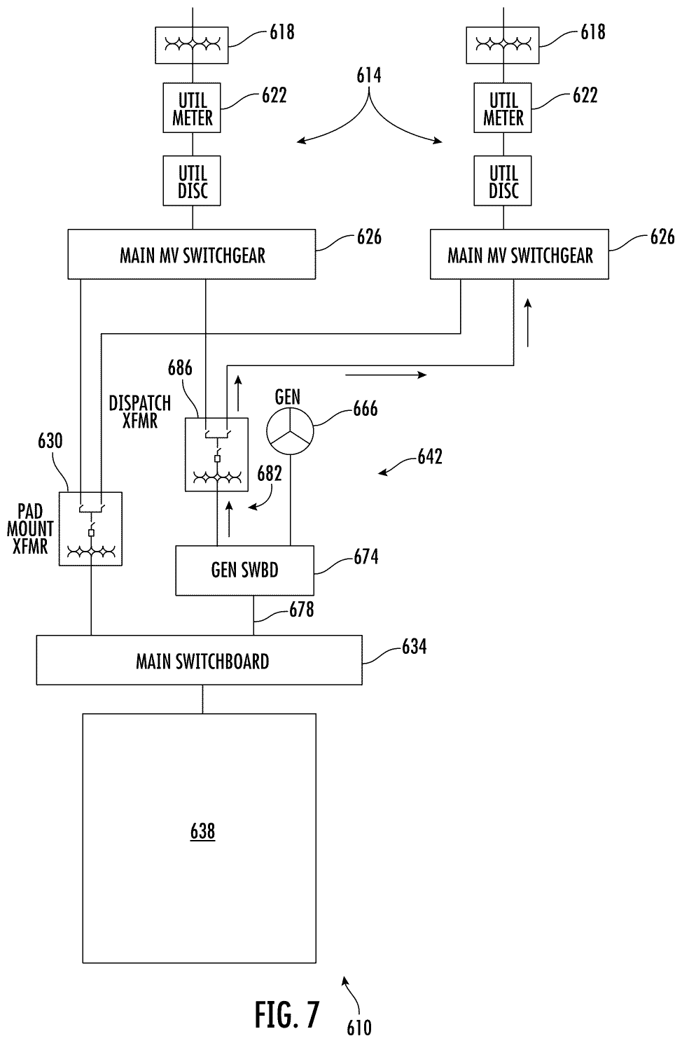

FIG. 7 illustrates an example data center power system 610 that includes another example backup power system 642.

In the example illustrated in FIG. 7, the data center power system 610 and the backup power system 642 include one or more utility connections 614, one or more utility transformers 618, one or more utility meters 622, one or more main switchgears 626, one or more pad mounted transformers 630, one or more main switchboards 634, one or more generators 666, one or more generator switchboards 674, one or more first pathways 678, one or more second pathways 682, and one or more dispatch transformers 686. The utility connection(s) 614, utility transformer(s) 618, utility meter(s) 622, main switchgear(s) 626, pad mounted transformer(s) 630, main switchboard(s) 634, generator(s) 666, generator switchboard(s) 574, first pathway(s) 578, second pathway(s) 582, and dispatch transformer(s) 586 are the same as (or substantially similar) to the utility connection(s) 14/114/514, utility transformer(s) 18/118/518, utility meter(s) 22/122/522, main switchgear(s) 26/126/526, pad mounted transformer(s) 30/130/530, main switchboard(s) 34/134/534, generators 166/566, generator switchboard(s) 574, first pathway(s) 578, second pathway(s) 582, and dispatch transformer(s) 586 of FIGS. 1-6 (discussed above). Furthermore, the data center 638 of FIG. 7 is the same as (or substantially similar to) the data center 38/138/538 of FIGS. 1-6 (discussed above).

However, unlike FIG. 6, the data center power system 610 includes two main switchgears 626 and two utility connections 614 (and the second pathway 682 includes a pathway to each of the two main switchgears 626 and the two utility connections 614). This configuration in FIG. 7 may be referred to as a loop configuration.

In some examples, one utility connection 614 and its respective one main switchgear 626 may be the utility connection that provides electricity to the data center 638, while the other utility connection 614 and its respective one main switchgear 626 may be the dispatch connection that allows dispatch power to be provided to the utility grid from the backup power system 642. This may, in some examples, allow full generator 666 capacity to be dispatched to the alternate main switchgear 626 while maintaining a primary power path through the primary main switchgear 626—thereby providing full isolation of the primary path for the building loads, in some examples. Additionally, in some examples, the dispatch connection may be a redundant connection that may be used to provide electricity to the data center 638 when the utility connection is not working, and the utility connection may be a redundant connection that allows dispatch power to be provided to the utility grid from the backup power system 642 when the dispatch connection is not working.

Modifications, additions, or omissions may be made to data center power system 610 and/or backup power system 642 without departing from the scope of the disclosure. For example, one or more components of data center power system 610 and/or backup power system 642 may be separated, combined, and/or eliminated. As one example of this, one or more of the transformers discussed above may be eliminated as needed. Additionally, in some examples, the backup power system 642 may also include one or more UPSs (e.g., UPSs 62, or UPSs 162) that may provide backup power to the data center 638 while the generator(s) 666 are starting up.

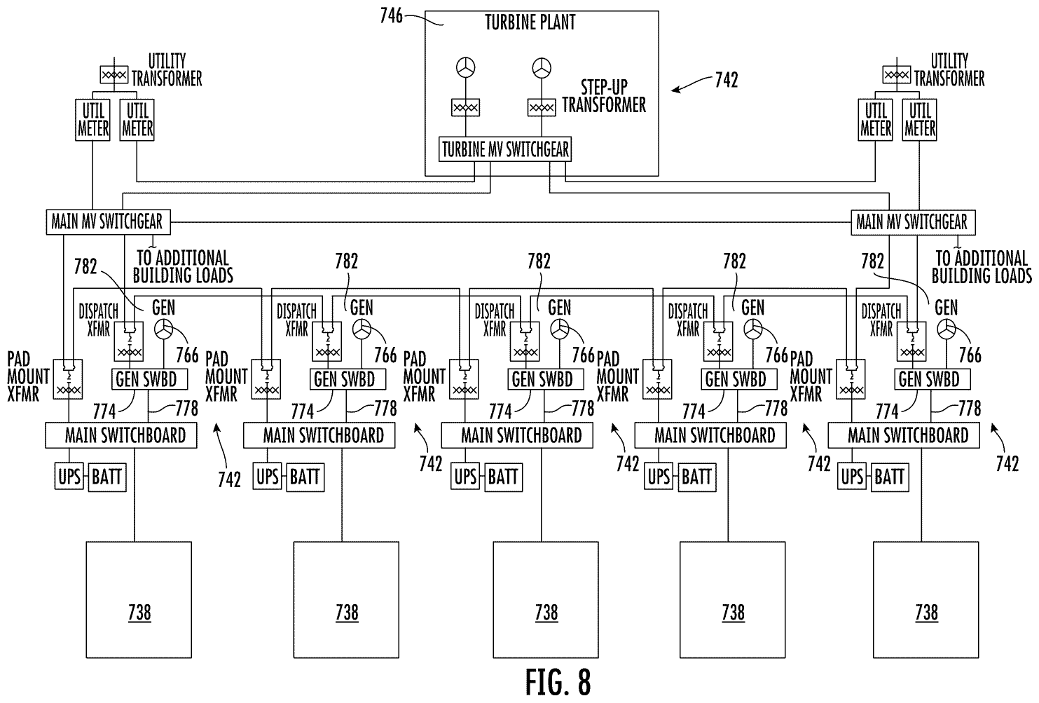

FIG. 8 illustrates an example data center power system 710 that includes another example backup power system 742. The components of the data center power system 710 of FIG. 8 and the backup power system 742 of FIG. 8 are the same as (or substantially similar) to the components of the data center power system 10/110/510/610 of FIGS. 1-7 and the backup power system 42/142/542/642 of FIGS. 1-7.

In the example illustrated in FIG. 8, the data center power system 710 and the backup power system 742 is a combination of the data center power systems 110/610 of FIGS. 2 and 7 (and their components) and the backup power systems 142/642 of FIGS. 2 and 7 (and their components). That is, the backup power system 742 includes a turbine plant 746 that may be used to provide backup power to the data center 738 and/or that may be used to provide dispatch power to the utility grid. Furthermore, the backup power system 742 further includes generator(s) 766 and generator switchboards 774 that may also be used to provide backup power to the data center 738 (e.g., while the turbine plant 746 is starting up) via the first pathway 778, and/or that may be used to provide dispatch power to the utility grid via the second pathway 782.

Modifications, additions, or omissions may be made to data center power system 710 and/or backup power system 742 without departing from the scope of the disclosure. For example, one or more components of data center power system 710 and/or backup power system 742 may be separated, combined, and/or eliminated. As one example of this, one or more of the transformers discussed above may be eliminated as needed. Furthermore, although the data center power system 710 and the backup power system 742 of FIG. 8 is illustrated as a combination of FIGS. 2 and 7, in other examples, the data center power system 710 and the backup power system 742 of FIG. 8 may be a combination of any two or more of the figures disclosed herein, such as, for example, FIGS. 1 and 7; FIGS. 2, 7, and 3, 4, and/or 5; FIGS. 1, 7, and 3, 4, and/or 5; or any other combination of two or more of the figures disclosed herein.

As is discussed above, the systems of FIGS. 1-8 may include one or more UPSs (e.g., UPSs 62, or UPSs 162). In some examples, the UPS of one or more of FIGS. 1-8 may be a battery-powered UPS that can be recharged using renewable or low carbon fuel. Additionally, in some examples, the control system (or another controller) may determine when the UPS needs to recharge, may determine that the UPS is recharging or is not recharging, may determine how to recharge the UPS (e.g., determine which power source to use), or any combination of the preceding. As one example of this, the control system may monitor when the UPS(s) needs to recharge (e.g., the control system may receive information from the UPS(s) that indicates when a recharge is needed), and the control system may select the power source accordingly. In some examples, if the utility grid is available and optionally if the grid can provide sufficient power at that time via renewable energy sources (such as renewable or low carbon fuel), the control system can select to recharge the UPS(s) from the utility grid. An another example, if the utility grid is available, but the grid cannot provide sufficient power at that time via renewable energy sources (such as renewable or low carbon fuel), the control system can select to recharge the UPS(s) from the generators and/or the turbine plant. In such an example, the control system may make sure that the percentage of renewable/low-carbon fuel being burned for the recharge is at least equal to the UPS(s)'s percentage of total load. As another example, if the utility grid is not available and the generators and/or the turbine plant are already being used to provide backup-power, the control system can select to recharge the UPS(s) from a portion of the backup power provided by the generators and/or the turbine plant. In such an example, the control system may make sure that the percentage of renewable/low-carbon fuel being burned for the recharge is at least equal to the UPS(s)'s percentage of total load.

In some examples, the control system may switch the data center to backup power (e.g., causing the generators and/or turbine plant to assume the building load), in order to recharge the UPS(s). In such an example, the backup power is used to power the data center and is further used to recharge the UPS(s). In doing so, the control system may ensure renewable and/or low carbon fuel source is selected for use in the generators and/or turbine plant. When the UPS(s) are fully recharged and the utility grid is available, the control system may switch the data center back to the utility grid (e.g., causing the utility grid to assume the building load). When the UPS(s) are fully recharged and the utility grid is not available, the control system may switch the fuel source for the backup power to the primary fuel source (as opposed to the renewable and/or low carbon fuel source, in some examples).

In various examples, the herein described systems (e.g., control systems), devices (e.g., transformers, generators, UPSs, turbines, turbine plants, switchboards, switchgears, etc.), components of the devices, and methods of operations may be implemented in or operated by software, firmware, or executable instructions stored in a data storage medium such as or including machine-readable medium. The term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding or carrying a set of instructions for execution by the machine and that cause the machine to perform any one or more of the methodologies of the present disclosure. Some examples may be implemented using a machine-readable medium or article which may store an instruction or a set of instructions that, if executed by a machine, may cause the machine to perform a method and/or operations in accordance with the examples. Such a machine may include, for example, any suitable processing platform, computing platform, computing device, processing device, computing system, processing system, computer, processor, or the like, and may be implemented using any suitable combination of hardware and/or software. The herein described systems (e.g., control systems), devices (e.g., transformers, generators, UPSs, turbines, turbine plants, switchboards, switchgears, etc.), and components of the devices, may include operatively associated computer-readable memory media such as memory for storing software applications and instructions used in obtaining, processing, storing or communicating data. Such memory can be internal, external, remote or local with respect to its operatively associated computer or computer system. Memory may also include any manner of storing software or other instructions including, for example and without limitation, solid state RAM storage, a hard disk, an optical disk, floppy disk, DVD, compact disc, memory stick, flash drive, compact disc flash drive, ROM (read only memory), RAM (random access memory), PROM (programmable ROM), EEPROM (extended erasable PROM), or other like computer-readable media. The machine-readable medium or article may include, for example, any suitable type of memory unit, memory device, memory article, memory medium, storage device, storage article, storage medium and/or storage unit, for example, memory, removable or non-removable media, solid state random access media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, various types of Digital Versatile Disk (DVD), a tape, a cassette, or the like.

Some of the examples as described hereinabove may be implemented in many different examples of instruction (e.g., software or firmware) and hardware. The instructions may include any suitable type of code, such as source code, compiled code, interpreted code, executable code, static code, dynamic code, and the like. The actual software code or specialized control hardware used to implement some of the illustrated examples do not limit the present disclosure. The instructions may be implemented, for example, using any suitable programing language, which may include high-level, low-level, object-oriented, visual, compiled or interpreted programming languages, such as, but not limited to, C, C++, C#, Java, BASIC, SQL, Perl, Matlab, Pascal, Visual BASIC, Go, Python, R, Java Script, Typescript, Objective C, Swift, assembly language, machine code, and so forth. The examples are not limited in this context.

In certain aspects, a single component may be replaced by multiple components, and multiple components may be replaced by a single component, to provide an element or structure or to perform a given function or functions. Except where such substitution would not be operative to practice certain examples of the present disclosure, such substitution is considered within the scope of the present disclosure. In one example, all or a portion of the system, its features or functional elements, modules, units, etc. or one or more steps of the method of operation may be associated with, implemented by, executed on, or embedded in (e.g., as embedded software/firmware) one or more hardware components. Further, such one or more components so configured may be installed or associated with one or more devices and therein configured to perform the herein described system functionalities or methods.

This specification has been written with reference to various non-limiting and non-exhaustive examples. However, it will be recognized by persons having ordinary skill in the art that various substitutions, modifications, or combinations of any of the disclosed examples (or portions thereof) may be made within the scope of this specification. Thus, it is contemplated and understood that this specification supports additional examples not expressly set forth in this specification. Such examples may be obtained, for example, by combining, modifying, or reorganizing any of the disclosed components, elements, features, aspects, characteristics, limitations, and the like, of the various non-limiting and non-exhaustive examples described in this specification. In this manner, Applicant reserves the right to amend the claims during prosecution to add features as variously described in this specification.

What is claimed is:

1. A system, comprising:
a backup power system for providing backup power to all or a portion of a data center, the backup power system comprising:
a turbine plant comprising one or more turbines; and
one or more uninterruptible power sources;
wherein the one or more uninterruptible power sources are configured to, following a power outage to the all or the portion of the data center, provide the backup power to the all or the portion of the data center;
wherein the one or more turbines of the turbine plant are configured to, following the power outage to the all or the portion of the data center, start a start up process; and
wherein the turbine plant is configured to, following the one or more turbines finishing the start up process, provide the backup power to the all or the portion of the data center.

2. The system of claim 1, further comprising the data center.

3. The system of claim 1, wherein the turbine plant is a multi-fuel turbine plant, and wherein the one or more turbines are each multi-fuel turbines.

4. The system of claim 1, further comprising one or more on-site fuel storage tanks configured to store enough fuel to run the one or more turbines of the turbine plant for 24 hours or more.

5. The system of claim 1, wherein the one or more uninterruptible power sources are further configured to provide the backup power to the all or the portion of the data center for 20 minutes or more.

6. The system of claim 1, wherein:
the backup power system further comprises one or more generators;
the one or more generators are configured to, following the power outage to the all or the portion of the data center, start a start up process; and
the one or more generators are further configured to, following the one or more generators finishing the start up process, provide the backup power to the all or the portion of the data center.

7. The system of claim 6, wherein:
the one or more uninterruptible power sources are further configured to provide the backup power to the all or the portion of the data center for 5 minutes or less; and
the system further comprises one or more additional on-site fuel storage tanks configured to store enough fuel to run the one or more generators for 30 minutes or more.

8. The system of claim 1, wherein:
the one or more turbines of the turbine plant are configured to, prior to the power outage or following a fix of the power outage to the all or the portion of the data center, start another start up process; and
the turbine plant is configured to, following the one or more turbines finishing the another start up process, provide dispatch power to a utility power grid.

9. The system of claim 8, wherein the turbine plant further comprises one or more turbine main switchboards, wherein the one or more turbine main switchboards are configured to receive electricity generated as a result of the one or more turbines, and further configured to provide the generated electricity to the utility power grid as the dispatch power.

10. A method, comprising:
following a power outage to all or a portion of a data center:
providing, by one or more uninterruptible power sources, backup power to the all or the portion of the data center; and
starting, by one or more turbines of a turbine plant, a start up process; and
following the one or more turbines of the turbine plant finishing the start up process, providing, by the turbine plant, the backup power to the all or the portion of the data center.

11. The method of claim 10, wherein the turbine plant is a multi-fuel turbine plant, and wherein the one or more turbines are each multi-fuel turbines.

12. The method of claim 10, further comprising storing, by one or more on-site fuel storage tanks, enough fuel to run the one or more turbines of the turbine plant for 24 hours or more.

13. The method of claim 10, wherein the providing, by the one or more uninterruptible power sources, the backup power to the all or the portion of the data center comprises providing, by the one or more uninterruptible power sources, the backup power to the all or the portion of the data center for 20 minutes or more.

14. The method of claim 10, further comprising:
following the power outage to the all or the portion of the data center, starting, by one or more generators, a start up process; and
following the one or more generators finishing the start up process, providing, by the one or more generators, the backup power to the all or the portion of the data center.

15. The method of claim 14, wherein:
the providing, by the one or more uninterruptible power sources, the backup power to the all or the portion of the data center comprises providing, by the one or more uninterruptible power sources, the backup power to the all or the portion of the data center for 5 minutes or less;
the method further comprises storing, by one or more additional on-site fuel storage tanks, enough fuel to run the one or more generators for 30 minutes or more.

16. The method of claim 10, further comprising:
prior to the power outage or following a fix of the power outage to the all or the portion of the data center, starting, by the one or more turbines of the turbine plant, another start up process; and
following the one or more turbines finishing the another start up process, providing, by the turbine plant, dispatch power to a utility power grid.

17. A system, comprising:
one or more memory units; and
one or more processors communicatively coupled to the one or more memory units, the one or more processors configured to:
following a power outage to all or a portion of a data center:
cause power from one or more uninterruptible power sources to be provided as backup power to the all or the portion of the data center; and
cause one or more turbines of a turbine plant to start a start up process; and
following the one or more turbines of the turbine plant finishing the start up process, cause power from the turbine plant to be provided as the backup power to the all or the portion of the data center.

18. The system of claim 17, wherein the one or more processors are further configured to:
following the power outage to the all or the portion of the data center, cause one or more generators to start a start up process; and
following the one or more generators finishing the start up process, cause power from the one or more generators to be provided as the backup power to the all or the portion of the data center.

19. The system of claim 17, wherein the one or more processors are further configured to:
prior to the power outage or following a fix of the power outage to the all or the portion of the data center, cause the one or more turbines of the turbine plant to start another start up process; and
following the one or more turbines finishing the another start up process, cause power from the turbine plant to be provided as dispatch power to a utility power grid.

20. A tangible non-transitory computer readable medium comprising logic configured, when executed by one or more processors, to:
following a power outage to all or a portion of a data center:
cause power from one or more uninterruptible power sources to be provided as backup power to the all or the portion of the data center; and
cause one or more turbines of a turbine plant to start a start up process; and
following the one or more turbines of the turbine plant finishing the start up process, cause power from the turbine plant to be provided as the backup power to the all or the portion of the data center.
